(19) United States
(12) Patent Application Publication
(10) Pub. No.: US 2023/0284383 A1
(43) Pub. Date: Sep. 7, 2023

(54) WIRING STRUCTURE

(71) Applicant: Nippon Telegraph and Telephone Corporation, Tokyo (JP)

(72) Inventors: Hitoshi Wakita, Tokyo (JP); Norio Sato, Tokyo (JP)

(21) Appl. No.: 18/002,830

(22) PCT Filed: Jul. 2, 2020
(86) PCT No.: PCT/JP2020/026029

§ 371 Date: Dec. 21, 2022

(51) Int. Cl. H05K 1/11

(52) U.S. Cl. CPC H05K 1/115

(57) ABSTRACT

A trace structure includes a first signal line in which a first outer layer conductor on a top surface of a dielectric substrate, a first via, a first inner layer conductor, a second via, and a second outer layer conductor on a bottom surface of the substrate are electrically connected, and a second signal line in which a third outer layer conductor on the top surface, a third via, a second inner layer conductor, a fourth via, and a fourth outer layer conductor on the bottom surface are electrically connected, and in which the first and second inner layer conductors have substantially equivalent lengths and are arranged on different planes each parallel to the bottom surface to overlap each other in a vertical direction, and a sum of lengths of the first and second vias is substantially equivalent to a sum of lengths of the third and fourth vias.

### CROSS-REFERENCE TO RELATED APPLICATIONS

This patent application is a national phase filing under section 371 of PCT Application no. PCT/JP2020/026029, filed on Jul. 2, 2020, which is incorporated herein by reference in its entirety.

### TECHNICAL FIELD

The present disclosure relates to a trace structure that transmits high-frequency signals.

### BACKGROUND

In recent years, an amount of data transmitted over a network goes on increasing, and the technique of improving the transmission rate of data to address the increase has been studied and developed. For high-speed data transmission and reception, differential signal transmission with high common-mode noise resistance is useful and is widely used for an integrated circuit (IC) and a high-speed electronic device such as a package substrate including an IC.

A differential signal is transmitted using two signal routes of data that has ideally a phase difference of 180 degrees, or that is positive-negative inverted. As a result, the common-mode noises can be canceled with each other. For example, NPLs 1 and 2 disclose a structure and design technique of an RF via differential trace structure in a multilayer trace substrate.

FIG. 6 is a differential trace structure described in NPL 1. In differential transmission of related art, skew adjustment between positive and negative signals is important. In the differential transmission, in which the signals that have the phase difference of 180 degrees or that are positive-negative inverted are transmitted through two signal routes, if a difference is generated between lengths of the signal routes, a difference in an arrival timing of the signals is generated at a receiving end between the positive data and the negative data even if the signals are transmitted with timings thereof being aligned from a transmission end, resulting in an increase in a common mode component to cause deterioration of a signal quality.

NPL 1 describes the structure and design technique in which, in differential trace pairs 61 and 62, a skew difference caused by a difference between an inside diameter and an outside diameter generated due to bends of two micro-strip differential signal lines disposed on an identical plane is suppressed by providing an excess length to the inside diameter of an inner signal line to physically equalize the signal line lengths.

FIGS. 7A and 7B illustrate a top view and a sectional side view of the differential trace structure described in NPL 2, respectively. The structure includes, in a Si substrate 71, an upper trace 72 and a lower trace 73 as inner layer conductors, and a via 74 connected to the lower trace 73. A broad side strip trace structure 75 is used that uses the inner layer conductors of the multilayer substrate to couple an electromagnetic field in a top-to-bottom direction, unlike a line structure called a micro-strip line (coupled pair) described in NPL1 in which the differential trace is disposed on the identical plane.

In the broad side strip trace structure 75, positive phase and negative phase signals are arranged above and below so that no difference between the inside diameter and the outside diameter is generated for both the positive phase and negative phase signals at a bend portion, and therefore, no signal skew difference is generated. On the other hand, use of the inner layer conductor causes a problem that lengths of vias reaching to the layers are different to generate a skew difference in a via portion.

In NPL 2, the signal traces 72 and 73 are disposed in the multilayer Si substrate 71 as a trace substrate. The via 74 is used in a connection part reaching to the lower trace 73, while the trace for the upper trace is expanded in the same layer without passing through a via. The via length in this structure is approximately several to ten micrometers, which is short enough compared to a wavelength of an assumed use band.

### Citation List

### Non Patent Literature

NPL 1: Chung-Pin Huang et al., “Signal integrity improvements of bended coupled lines by using miniaturized capacitance and inductance compensation structures”, Proceedings of 2016 Asia-Pacific International Symposium on Electromagnetic Compatibility (APEMC), pp. 22-23.

NPL 2: Jason W. May et al., “A 40-50-GHz SiGe 1 : 8 differential power divider using shielded broadside-coupled striplines”, IEEE Transactions on Microwave Theory and Techniques, Vol. 56, No. 7 (2008), pp. 1575-1581.

### SUMMARY

### Technical Problem

However, in the structure described in NPL 1 illustrated in FIG. 6, there is a need to ensure an inter-channel clearance 63 in order to suppress crosstalk between channels on a substrate in which a plurality of the differential trace pairs 61 and 62 exist, but the excess length provision causes an area required for equalizing the signal line lengths to be increased, which is a problem in making the differential trace multi-channel.

In the structure described in NPL 2 illustrated in FIGS. 7A and 7B, an asymmetric structure is located between the positive and negative signal routes, and thus, an interlayer thickness is approximately hundreds of microns to one millimeter in a commonly used multilayer ceramic substrate or resin substrate. Therefore, because the difference between the via lengths due to the presence or absence of the via between the differential lines cannot be ignored, the skew difference cannot be ignored. As a result, conversion from a differential mode to a common mode occurs to disadvantageously degrade characteristics.

### Means for Solving the Problem

A trace structure according to embodiments of the present disclosure includes a first signal line in which a first outer layer conductor disposed on a top surface of a dielectric substrate, a first via, a first inner layer conductor disposed inside the dielectric substrate, a second via, and a second outer layer conductor disposed on a bottom surface of the dielectric substrate are electrically connected to each other, and a second signal line in which a third outer layer conductor disposed on the top surface of the dielectric substrate, a third via, a second inner layer conductor disposed inside the dielectric substrate, a fourth via, and a fourth outer layer conductor disposed on the bottom surface of the dielectric substrate are electrically connected to each other, in which the first inner layer conductor and the second inner layer conductor have substantially the same shapes and are arranged on different planes each parallel to the bottom surface to overlap each other in a vertical direction, and a sum of a length of the first via and a length of the second via is substantially equivalent to a sum of a length of the third via and a length of the fourth via.

### Effects of Embodiments of the Invention

According to embodiments of the present disclosure, a trace structure can be provided which suppresses a skew difference between differential signal lines and has good high-frequency characteristics.

### BRIEF DESCRIPTION OF THE DRAWINGS

FIG. 1A is a top perspective view of a trace structure according to a first embodiment of the present disclosure.

FIG. 1B is a cross-sectional perspective view taken along a line IB-IB′ in the top view of the trace structure according to the first embodiment of the present disclosure.

FIG. 1C is a cross-sectional perspective view taken along a line IC-IC′ in the top view of the trace structure according to the first embodiment of the present disclosure.

FIG. 2A is a top perspective view of a trace structure according to a second embodiment of the present disclosure.

FIG. 2B is a cross-sectional view taken along a line IIB-IIB′ in the top perspective view of the trace structure according to the second embodiment of the present disclosure.

FIG. 2C is a cross-sectional perspective view taken along a line IIC-IIC′ in the top view of the trace structure according to the second embodiment of the present disclosure.

FIG. 3A is a top perspective view of a trace structure according to a third embodiment of the present disclosure.

FIG. 3B is a cross-sectional perspective view taken along a line IIIB-IIIB′ in the top view of the trace structure according to the third embodiment of the present disclosure.

FIG. 3C is a cross-sectional perspective view taken along a line IIIC-IIIC′ in the top view of the trace structure according to the third embodiment of the present disclosure.

FIG. 4A is a top perspective view of a trace structure according to a fourth embodiment of the present disclosure.

FIG. 4B is a cross-sectional perspective view taken along a line IVB-IVB′ in the top view of the trace structure according to the fourth embodiment of the present disclosure.

FIG. 4C is a cross-sectional perspective view taken along a line IVC-IVC′ in the top view of the trace structure according to the fourth embodiment of the present disclosure.

FIG. 5A is a top perspective view of a signal trace in a trace structure according to a fifth embodiment of the present disclosure.

FIG. 5B is a top perspective view of a signal trace for describing the trace structure according to the fifth embodiment of the present disclosure.

FIG. 6 is a diagram for explaining a trace structure of related art.

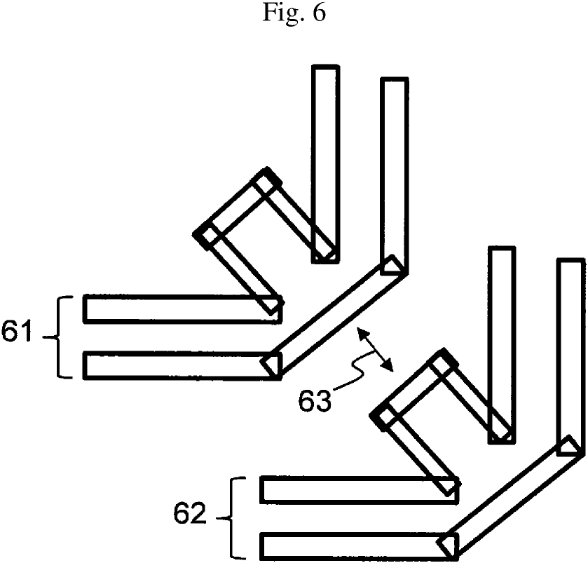

FIG. 7A is a diagram (top view) for describing a trace structure of related art.

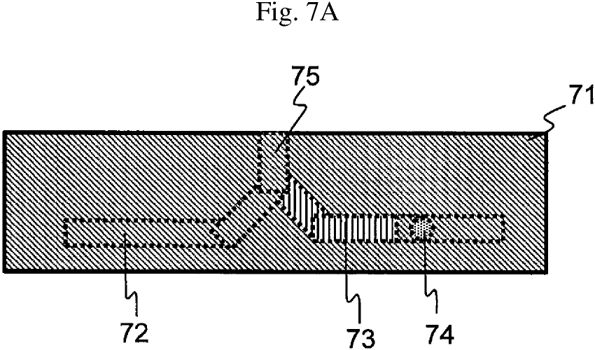

FIG. 7B is a diagram (sectional side view) for describing the trace structure of related art.

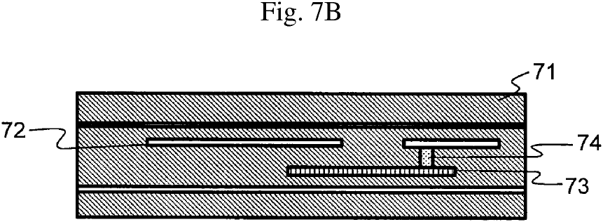

### DETAILED DESCRIPTION OF ILLUSTRATIVE EMBODIMENTS

### First Embodiment

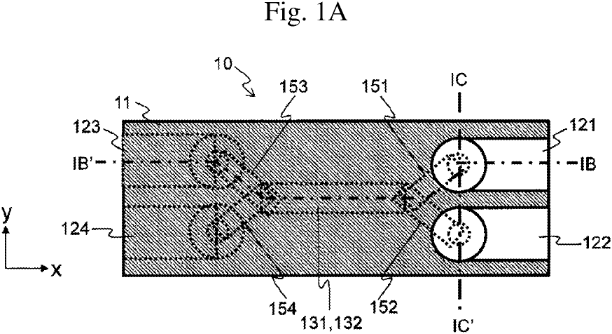

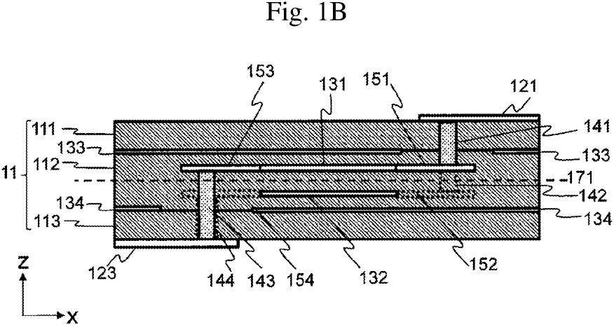

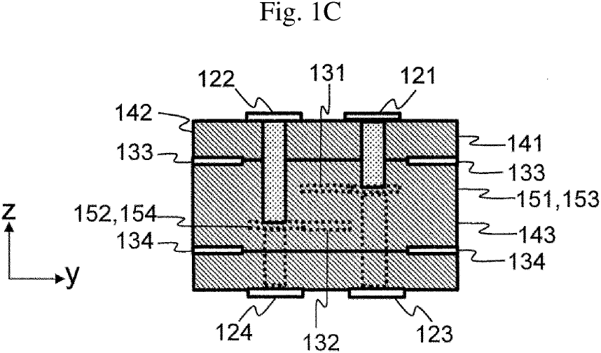

A first embodiment of the present disclosure will be described with reference to FIGS. 1A to 1C.

### Configuration of Trace Structure

FIGS. 1A, 1B, and 1C respectively illustrate a top view of a trace structure 10 according to the present embodiment, a cross-sectional view taken along a line IB-IB′ in the top view, and a cross-sectional view taken along a line IC-IC′ in the top view.

The trace structure 10 includes a dielectric 11 used as a substrate, outer layer conductors 121 and 122 on a top surface of the dielectric 11, and outer layer conductors 123 and 124 on a bottom surface of the dielectric 11. The trace structure 10 also includes, in an inner layer of the dielectric 11, inner layer conductors 131 to 134, vias 141 to 144, and expansion parts 151 to 154.

The dielectric 11 includes an upper layer 111, an intermediate layer 112, and a lower layer 113, a layer thickness of each layer is approximately from 80 µm to 100 µm, and a material thereof is ceramic.

The inner layer conductors 131 and 132 have a width of 60 to 70 µm and a length of 20 mm and have the substantially equivalent (including equivalent) lengths. Shapes of the inner layer conductors 131 and 132 are not limited to the above but are desirably substantially equivalent (including equivalent).

The vias 141 and 144 have a cross-sectional diameter of 80 µm φ diameter and a length of approximately 100 µm. As such, the vias 141 and 144 have the substantially equivalent (including equivalent) lengths. The vias 141 and 144 desirably have substantially equivalent (including equivalent) shapes.

The vias 142 and 143 have a cross-sectional diameter of 80 µm φ diameter and a length of approximately 200 µm. As such, the vias 142 and 143 have the substantially equivalent (including equivalent) lengths. The vias 142 and 143 desirably have substantially equivalent (including equivalent) shapes.

The expansion parts 151 to 154 have a width of 60 to 70 µm and a length of approximately 0.5 to 1 mm and have the same shapes. In this way, the expansion parts 151 to 154 desirably have the substantially equivalent (including equivalent) lengths and desirably have the substantially equivalent (including equivalent) shapes.

The outer layer conductor 121 is connected to one end portion of the via 141, and the other end portion is connected to one end portion of the expansion part 151. The other end portion of the expansion part 151 is connected to one end portion of the inner layer conductor 131, and the other end portion of the inner layer conductor 131 is connected to one end portion of the expansion part 153. The other end portion of the expansion part 153 is connected to one end portion of the via 143. The other end portion of the via 143 is connected to the outer layer conductor 123 on the bottom surface of the dielectric 11.

In this manner, the outer layer conductor 121, the via 141, the inner layer conductor 131, the via 143, and the outer layer conductor 123 are electrically connected to each other.

According to this configuration, a positive phase of a differential signal is input to the outer layer conductor 121 on the top surface of the dielectric 11 and transmitted to the outer layer conductor 123 on the bottom surface of the dielectric 11.

Similarly, the outer layer conductor 122 is connected to the via 142, the expansion part 152, the inner layer conductor 132, the expansion part 154, the via 144, and the outer layer conductor 124 in order.

In this manner, the outer layer conductor 122, the via 142, the inner layer conductor 132, the via 144, and the outer layer conductor 124 are electrically connected to each other.

According to this configuration, a negative phase of a differential signal is input to the outer layer conductor 122 on the top surface of the dielectric 11 and transmitted to the outer layer conductor 124 on the bottom surface of the dielectric 11.

Here, the inner layer conductor 131 and the inner layer conductor 132 are wired on different planes parallel to the bottom surface of the dielectric 11 (an x-y plane in FIG. 1) to overlap each other in a vertical direction (in a z direction in the figure), forming a broad side strip trace structure.

At this time, the inner layer conductor 131 and the inner layer conductor 132 are located symmetrically with respect to the x-y plane (hereinafter, referred to as a “substrate center plane”) 171 that is positioned at the center in a layer direction (the z direction in FIG. 1) of the dielectric 11 (substrate).

In this structure, a sum of the lengths of the vias 141 and 143 is substantially equivalent (including equivalent) to a sum of the lengths of the vias 142 and 144. Thus, a length of a route from the outer layer conductor 121 to the outer layer conductor 123 is equal to a length of a route from the outer layer conductor 122 to the outer layer conductor 124, and thus, there is no skew difference caused by a route difference.

Furthermore, the inner layer conductor 133 and the inner layer conductor 134 are wired, as ground conductors, symmetrically with respect to the substrate center plane, where the inner layer conductor 133 is wired over the inner layer conductor 131 and the inner layer conductor 134 is wired under the inner layer conductor 132, functioning as grounds of a broad side differential trace.

In this manner, the inner layer conductor 133 and the inner layer conductor 134 are disposed as the ground conductors to sandwich the first inner layer conductor and the second inner layer conductor in a top-to-bottom direction.

The introduction of the ground conductors including the inner layer conductor 133 and the inner layer conductor 134 can suppress unnecessary coupling between channels or unnecessary coupling with other structures in a package substrate, for example, conductor patterns of front and back layers, chips, and the like, to provide a structure more excellent in crosstalk characteristics.

As a result of inputting and transmitting the positive and negative differential signals to the trace structure 10, good high-frequency characteristics can be obtained.

In particular, in a case that each of the conductors transmitting the positive and negative differential signals has a trace bending configuration, a trace substrate structure of related art has conductors wired on the same plane, and thus, it is difficult to prevent the skew difference caused by an inside diameter difference and an outside diameter difference between the conductors.

On the other hand, according to the trace structure of the present embodiment, it is easy to prevent the skew differences caused by the inside diameter difference and the outside diameter difference between the conductors because the inner layer conductors 131 and 132 are wired in the top-to-bottom direction.

According to the trace structure of the present embodiment, the differential signal can be transmitted in the top-to-bottom direction of the substrate, and the differential signal can be transmitted with good high-frequency characteristics without generating a skew difference. Furthermore, a trace area can be reduced to allow efficient wiring on the substrate.

### Second Embodiment

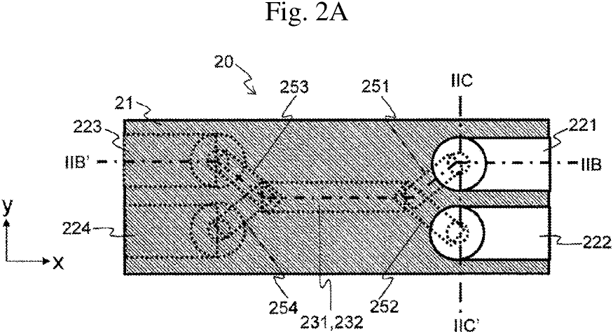

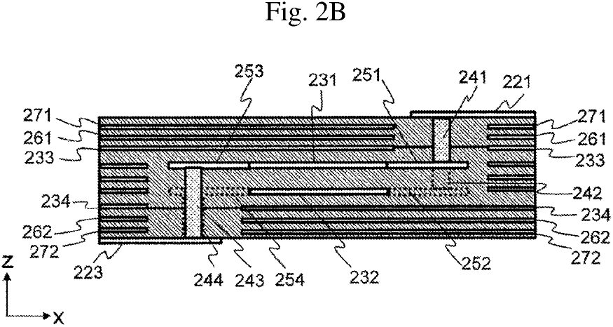

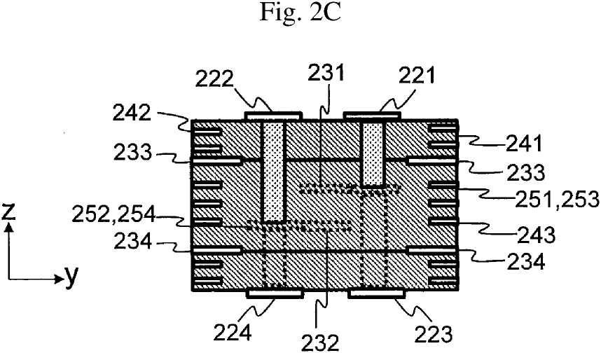

Next, a trace structure according to a second embodiment of the present disclosure will be described with reference to FIGS. 2A to 2C. A trace structure 20 according to the present embodiment has a configuration substantially similar (including similar) to the trace structure 10 according to the first embodiment and has similar effects. The trace structure 20 is different in including conductors having functions of a ground, a power supply, and the like, in addition to the configuration of the trace structure 10.

### Configuration of Trace Structure

FIGS. 2A, 2B, and 2C respectively illustrate a top view of the trace structure 20 according to the present embodiment, a cross-sectional view taken along a line IIB-IIB′ in the top view, and a cross-sectional view taken along a line IIC-IIC′ in the top view.

The trace structure 20 includes a dielectric 21 used as a substrate, outer layer conductors 221 and 222 on a top surface of the dielectric 21, and outer layer conductors 223 and 224 on a bottom surface of the dielectric 21. The trace structure 20 also includes, in an inner layer of the dielectric 21, inner layer conductors 231 to 234, vias 241 to 244, and expansion parts 251 to 254.

Similarly to the first embodiment, the outer layer conductor 221 is connected to the via 241, the expansion part 251, the inner layer conductor 231, the expansion part 253, the via 243, and the outer layer conductor 223 in order.

According to this configuration, a positive phase of a differential signal is input to the outer layer conductor 221 on the top surface of the dielectric 21 and transmitted to the outer layer conductor 223 on the bottom surface of the dielectric 21.

Similarly, the outer layer conductor 222 is connected to the via 242, the expansion part 252, the inner layer conductor 232, the expansion part 254, the via 244, and the outer layer conductor 224 in order.

According to this configuration, a negative phase of a differential signal is input to the outer layer conductor 222 on the top surface of the dielectric 21 and transmitted to the outer layer conductor 224 on the bottom surface of the dielectric 21.

In this way, the broad side strip trace is configured inside the dielectric 21.

The trace structure 20 includes the inner layer conductor 233 and the inner layer conductor 234 above and below the inner layer conductor 231 and the inner layer conductor 232 constituting the broad side strip trace. The inner layer conductor 233 and the inner layer conductor 234 function as grounds.

The inner layer conductor 133 and the inner layer conductor 134 can suppress unnecessary coupling between channels or unnecessary coupling with other structures in a package substrate, for example, conductor patterns of front and back layers, chips, and the like, to provide a structure more excellent in crosstalk characteristics.

Also, conductors 261 and 262 are included in an upper layer and a lower layer, respectively, of the trace structure 20. The inner layer conductors 261 and 262 function as power supply lines.

Also, conductors 271 and 272 are included in the upper layer and the lower layer, respectively, of the trace structure 20. The conductors 271 and 272 cause the upper layer and the lower layer to function as ground layers, respectively.

According to the trace structure of the present embodiment, the differential signal can be transmitted with good high-frequency characteristics and the efficient wiring can be provided, and a variety of functions such as the ground function and the power supply function can be provided.

### Third Embodiment

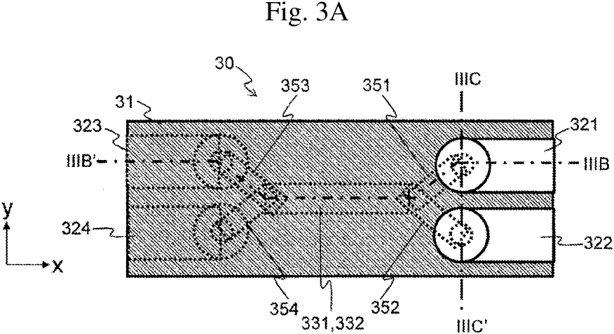

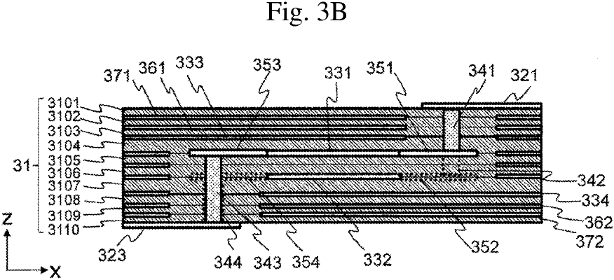

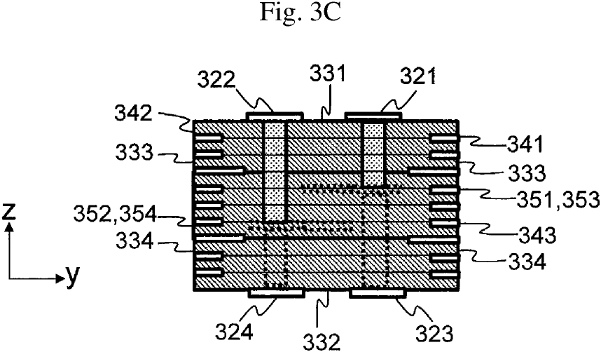

Next, a trace structure according to a third embodiment of the present disclosure will be described with reference to FIGS. 3A to 3C. A trace structure 30 according to the present embodiment has a configuration substantially similar (including similar) as the trace structures 10 and 20 according to the first and second embodiments, respectively, and has similar effects. The trace structure 30 differs from the trace structure 10 in that the dielectric 31 includes more layers compared to the trace structure 10.

### Configuration of Trace Structure

FIGS. 3A, 3B, and 3C respectively illustrate a top view of the trace structure 30 according to the present embodiment, a cross-sectional view taken along a line IIIB-IIIB′ in the top view, and a cross-sectional view taken along a line IIIC-IIIC′ in the top view.

The trace structure 30 includes a dielectric 31 used as a substrate, outer layer conductors 321 and 322 on a top surface of the dielectric 31, and outer layer conductors 323 and 324 on a bottom surface of the dielectric 31. The trace structure 30 also includes, in an inner layer of the dielectric 31, inner layer conductors 331 to 334, vias 341 to 344, and expansion parts 351 to 354.

Similarly to the first embodiment, the outer layer conductor 321 is connected to the via 341, the expansion part 351, the inner layer conductor 331, the expansion part 353, the via 343, and the outer layer conductor 323 in order.

According to this configuration, a positive phase of a differential signal is input to the outer layer conductor 321 on the top surface of the dielectric 31 and transmitted to the outer layer conductor 323 on the bottom surface of the dielectric 31.

Similarly, the outer layer conductor 322 is connected to the via 342, the expansion part 352, the inner layer conductor 332, the expansion part 354, the via 344, and the outer layer conductor 324 in order.

According to this configuration, a negative phase of a differential signal is input to the outer layer conductor 322 on the top surface of the dielectric 31 and transmitted to the outer layer conductor 324 on the bottom surface of the dielectric 31.

In this way, the broad side strip trace is configured inside the dielectric 31.

In the trace structure 30, the dielectric 31 includes ten layers of dielectric layers 3101 to 3110. The respective layers have substantially equivalent (including equivalent) layer thicknesses of approximately tens to hundreds of µm and are made from the same material. The material includes a ceramic substrate material such as high temperature co-fired ceramics (HTCC) and low temperature co-fired ceramics (LTCC), and a resin material as a build-up substrate material.

The trace structure 30 is manufactured by forming a pattern of a metal conductor or the like on a surface of each layer, and then, laminating the layers and firing.

According to the trace structure 30 of the present embodiment, the differential signal can be transmitted with good high-frequency characteristics and the efficient wiring can be provided, and because of being configured to have a multilayer structure of the layers that have the substantially equivalent layer thicknesses and are made from the same material, a complex trace structure can be easily formed in the dielectric and electromagnetic field environments around the traces in the dielectric can be the same, and thus, the skew difference of the differential signal can be easily taken into account.

### Fourth Embodiment

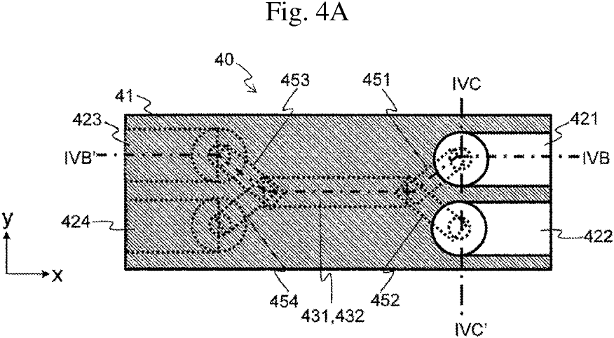

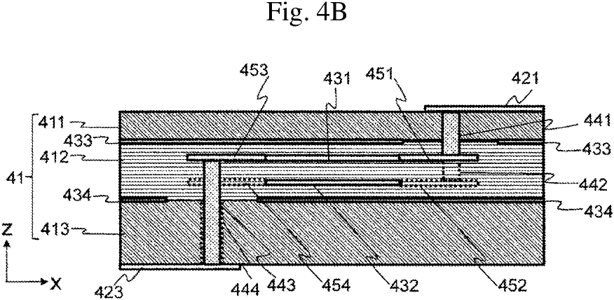

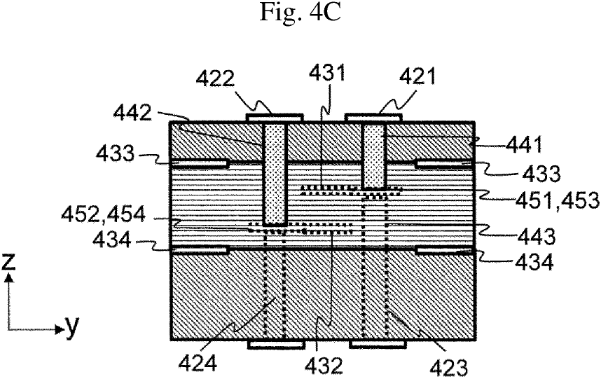

Next, a trace structure according to a fourth embodiment of the present disclosure will be described with reference to FIGS. 4A to 4C. A trace structure 40 according to the present embodiment has a configuration substantially similar (including similar) to the trace structure 10 according to the first embodiment and has similar effects. The trace structure 40 differs from the trace structure 10 in including a composite material substrate in which a material of an upper layer 411 and a lower layer 413 of the dielectric 41 is different from a material of an intermediate layer 412.

### Configuration of Trace Structure

FIGS. 4A, 4B, and 4C respectively illustrate a top view of the trace structure 40 according to the present embodiment, a cross-sectional view taken along a line IVB-IVB′ in the top view, and a cross-sectional view taken along a line IVC-IVC′ in the top view.

The trace structure 40 includes a dielectric 41 used as a substrate, outer layer conductors 421 and 422 on a top surface of the dielectric 41, and outer layer conductors 423 and 424 on a bottom surface of the dielectric 41. The trace structure 40 also includes, in an inner layer of the dielectric 41, inner layer conductors 431 to 434, vias 441 to 444, and expansion parts 451 to 454.

Similarly to the first embodiment, the outer layer conductor 421 is connected to the via 441, the expansion part 451, the inner layer conductor 431, the expansion part 453, the via 443, and the outer layer conductor 423 in order.

According to this configuration, a positive phase of a differential signal is input to the outer layer conductor 421 on the top surface of the dielectric 41 and transmitted to the outer layer conductor 423 on the bottom surface of the dielectric 41.

Similarly, the outer layer conductor 422 is connected to the via 442, the expansion part 452, the inner layer conductor 432, the expansion part 454, the via 444, and the outer layer conductor 424 in order.

According to this configuration, a negative phase of a differential signal is input to the outer layer conductor 422 on the top surface of the dielectric 41 and transmitted to the outer layer conductor 424 on the bottom surface of the dielectric 41.

In this way, the broad side strip trace is configured inside the dielectric 41.

In the trace structure 40, the material of the upper layer 411 and the lower layer 413 of the dielectric 41 is different from the material of the intermediate layer 412.

In the intermediate layer 412 of the dielectric 41, the inner layer conductor 431 and the inner layer conductor 432 constitute the broad side strip trace, where the electromagnetic field is concentrated between the inner layer conductor 431 and the inner layer conductor 432, and thus, a material having a low dielectric constant is desirably disposed in a layer between the inner layer conductor 431 and the inner layer conductor 432. The material having a low dielectric constant includes a fluororesin substrate or the like, and the dielectric constant thereof is approximately 2 to 3.

On the other hand, in the trace structure 40, the function of supplying power or the function as the ground is also required in addition to the function of transmitting a differential signal. The layers having these functions, in which the high-frequency signals are not transmitted, are not necessarily made from the material having the low dielectric constant. Thus, in order to reduce the cost, a glass-resin composite material called a flame retardant type 4 (FR4) material or the like is used.

As a result, in the dielectric substrate 41, the fluororesin material and the FR4 material are laminated in a composite manner. Specifically, the material of the intermediate layer 412 of the dielectric substrate 41 is the fluororesin material, and the material of the upper layer 411 and the lower layer 413 of the dielectric substrate 41 is the FR4 material.

Thus, the dielectric constants of the inner layer conductor 431 and the inner layer conductor 432 layer are lower than a dielectric constant of a layer not including the inner layer conductor 431 and the inner layer conductor 432 layer.

In a case that the dielectric material differs from layer to layer like this, an electrical length in the via connecting the layers effectively differs depending on the dielectric constant of each layer. It is also conceivable that the effective difference in the electrical length of the via causes a skew difference to be generated.

However, in the configuration of the trace structure 40, the number of interlayer vias for transmitting the positive phase signal and the negative phase signal is the same in each layer, and so, even in the configuration in which the interlayer material is different, a sum of the electrical lengths in the transmission route of the positive phase signal is equal to a sum of the electrical lengths in the transmission route of the negative phase signal, and thus, no skew difference is generated.

Here, in the upper layer 411 of the dielectric substrate 41, the inner layer conductor 431 may be disposed on the top surface and the inner layer conductor 432 may be disposed below the inner layer conductor 431 to constitute the broad side strip trace. In this case, a fluororesin substrate or the like as a material having a low dielectric constant is used for the upper layer 411, and a glass-resin composite material such as FR4 or a resin material such as a prepreg is used for the intermediate layer 412 and the lower layer 413.

In the lower layer 413 of the dielectric substrate 41, the inner layer conductor 432 may be disposed on the bottom surface and the inner layer conductor 431 may be disposed over the inner layer conductor 432 to constitute the broad side strip trace. In this case, a fluororesin substrate or the like as a material having a low dielectric constant is used for the lower layer 413, and a glass-resin composite material such as FR4 is used for the intermediate layer 412 and the upper layer 411.

In this manner, in the trace structure according to the present embodiment, the dielectric constants of the inner layer conductor 431 and the inner layer conductor 432 layer are lower than a dielectric constant of a layer not including the inner layer conductor 431 and the inner layer conductor 432 layer.

In this manner, in a case that the broad side strip trace is configured in the upper layer or the lower layer, the trace structure can be manufactured by laminating and penetrating, by the via, a high-frequency substrate (dielectric layer) including the inner layer conductor 431 and the inner layer conductor 432 in the front surface and the back surface, and the resin material such as FR4 or prepreg, and thus, a cost for the manufacturing can be lower than manufacturing using the build-up configuration substrate.

According to the trace structure of the present embodiment, the differential signal can be transmitted with good high-frequency characteristics and the efficient wiring can be provided, and the trace structure can be manufactured at a lower cost.

### Fifth Embodiment

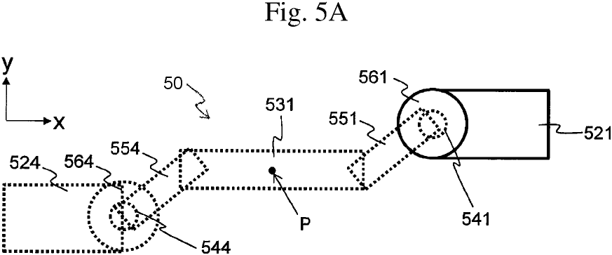

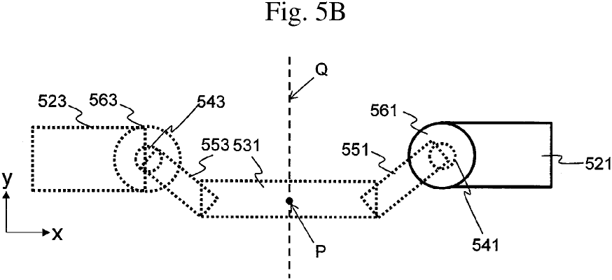

Next, a trace structure according to a fifth embodiment of the present disclosure will be described with reference to FIGS. 5A and 5B. A trace structure 50 according to the present embodiment has a configuration substantially similar (including similar) as the trace structure 10 according to the first embodiment and has similar effects. The trace structure 50 is different from the trace structure 10 in a trace base route from an outer layer conductor on a top surface to an outer layer conductor on a bottom surface.

### Configuration of Trace Structure

The trace structure 50 according to the fifth embodiment includes a dielectric 51 used as a substrate, outer layer conductors 521 and 522 on a top surface of the dielectric 51, and outer layer conductors 523 and 524 on a bottom surface of the dielectric 51, similar to the first embodiment. The trace structure 50 also includes, in an inner layer of the dielectric 51, inner layer conductors 531 to 534, vias 541 to 544, and expansion parts 551 to 554.

FIG. 5A illustrates a transmission route of one of the positive and negative differential signals in the trace structure 50.

An outer layer conductor 521 on the top surface of the dielectric 51 (not illustrated) is connected to one end portion of the via 541 through a connection part 561, and the other end portion is connected to one end portion of the expansion part 551. The other end portion of the expansion part 551 is connected to one end portion of the inner layer conductor 531, and the other end portion of the inner layer conductor 531 is connected to one end portion of the expansion part 554. The other end portion of the expansion part 554 is connected to one end portion of the via 544. The other end portion of the via 544 is connected to the outer layer conductor 524 on the bottom surface of the dielectric 51 through a connection part 564.

According to this configuration, a positive phase of a differential signal is input to the outer layer conductor 521 on the top surface of the dielectric 51 and transmitted to the outer layer conductor 524 on the bottom surface of the dielectric 51.

For the other transmission route (not illustrated) of the positive and negative differential signals in the trace structure 50, similarly, an outer layer conductor 522 on the top surface of the dielectric 51 is connected to a via 542, an expansion part 552, an inner layer conductor 532, an expansion part 553, a via 543, and an outer layer conductor 523 in order.

According to this configuration, a negative phase of a differential signal is input to the outer layer conductor 522 on the top surface of the dielectric 51 and transmitted to the outer layer conductor 523 on the bottom surface of the dielectric 51.

In this configuration, the inner layer conductor 531 and the inner layer conductor 532 constitute the broad side strip trace.

In this configuration, the signal input from the outer layer conductor 521 on the top surface, for example, the positive phase differential signal, is output to the outer layer conductor 524 on the bottom surface. The outer layer conductor 521 and the outer layer conductor 524 are located point-symmetrically with respect to a center point P of the inner layer conductor 531 when viewed.

On the other hand, the signal input from the outer layer conductor 522 on the top surface, for example, the negative phase differential signal, is output to the outer layer conductor 523 on the bottom surface. The outer layer conductor 522 and the outer layer conductor 523 are located point-symmetrically with respect to a center point P′ of the inner layer conductor 532.

That is, in this configuration, the end portion of the via 541 proximate to the top surface of the dielectric 51 and the end portion of the via 544 proximate to the bottom surface of the dielectric 51 are arranged to be point-symmetric with respect to the center point of the inner layer conductor 531, and the end portion of the via 542 proximate to the top surface of the dielectric 51 and the end portion of the via 543 proximate to the bottom surface of the dielectric 51 are arranged to be point-symmetric with respect to the center point of the inner layer conductor 532.

For comparison purpose, FIG. 5B illustrates a transmission route of one of the positive and negative differential signals similar to the trace structure 10 according to the first embodiment.

The outer layer conductor 521 is connected to the connection part 561, the via 541, the expansion part 551, the inner layer conductor 531, the expansion part 553, the via 543, the connection part 563, and the outer layer conductor 523 in order.

According to this configuration, a positive phase of a differential signal is input to the outer layer conductor 521 on the top surface of the dielectric 51 and transmitted to the outer layer conductor 523 on the bottom surface of the dielectric 51.

Similarly, the outer layer conductor 522 is connected to the connection part 562, the via 542, the expansion part 552, the inner layer conductor 532, the expansion part 554, the via 544, the connection part 564, and the outer layer conductor 524 in order.

According to this configuration, a negative phase of a differential signal is input to the outer layer conductor 522 on the top surface of the dielectric 51 and transmitted to the outer layer conductor 524 on the bottom surface of the dielectric 51.

In this configuration, the signal input from the outer layer conductor 521 on the top surface, for example, the positive phase differential signal, is output to the outer layer conductor 523 on the bottom surface. The outer layer conductor 521 and the outer layer conductor 523 are located line-symmetrically with respect to a center line Q of the inner layer conductor 531 (a line through the center point P in the y direction perpendicular to a signal transmission direction) when viewed from the top surface.

On the other hand, the signal input from the outer layer conductor 522 on the top surface, for example, the negative phase differential signal, is output to the outer layer conductor 524 on the bottom surface. The outer layer conductor 522 and the outer layer conductor 524 are located line-symmetrically with respect to a center line Q′ of the inner layer conductor 532 (a line through the center point P′ in the y direction perpendicular to the signal transmission direction) when viewed from the top surface.

That is, in this configuration, when viewed from the top surface, the via 541 and the via 543 are arranged to be line-symmetric with respect to the center line of the inner layer conductor 531 (the line through the center point and perpendicular to the signal transmission direction), and the via 542 and the via 544 are arranged to be line-symmetric with respect to the center line of the inner layer conductor 532 (the line through the center point and perpendicular to the signal transmission direction).

In this manner, between the configuration illustrated in FIG. 5A and the configuration illustrated in FIG. 5B, the positive phase and the negative phase of the differential signals output to the outer layer conductors 523 and 524 on the bottom surface are inverted.

As described above, according to the trace structure of the present embodiment, a sign (positive or negative) of the output differential signal can be easily inverted by changing the connection of the expansion part.

As a result, in a case that a printed circuit board (PCB) substrate is disposed under the dielectric 51 and the outer layer conductor on the bottom surface of the dielectric 51 is connected to the trace of the PCB substrate, a degree of freedom of layout of the trace of the PCB substrate can be increased.

In the present embodiment, as illustrated in FIGS. 5A and 5B, the example is illustrated in which the outer layer conductor on the top surface and the outer layer conductor on the bottom surface are located point-symmetrically or line-symmetrically when viewed from above, but these outer layer conductors may be arranged to be located asymmetrically.

As illustrated in FIGS. 5A and 5B, if the positional relationship between the outer layer conductor on the top surface and the outer layer conductor on the bottom surface is symmetric, in a case that a ball grid array (BGA) is used on the bottom surface, the arrangement of the BGA causes the arrangement of the outer layer conductor on the top surface to be limited.

On the other hand, if the outer layer conductor on the top surface and the outer layer conductor on the bottom surface are arranged to be located asymmetrically, in the case that the BGA is arranged on the bottom surface of the dielectric substrate, the arrangement of the BGA on the bottom surface does not cause the arrangement of the outer layer conductor on the top surface to be limited. As a result, the connection part (pad) on the top surface, for example, a pad for connecting to a chip, can be disposed at any position, and a degree of freedom of the chip mounting can be increased.

According to the trace structure of the present embodiment, the differential signal can be transmitted with good high-frequency characteristics and efficient wiring can be provided, and the degree of freedom of layout of the trace can be increased.

The embodiments of the present disclosure illustrate an example in which a positive phase differential signal is input to the outer layer conductor 121 and a negative phase differential signal is input to the outer layer conductor 122, but a negative phase differential signal may be input to the outer layer conductor 121 and a positive phase differential signal may be input to the outer layer conductor 122.

The embodiments of the present disclosure illustrate an example in which the signal connection structure includes one set of differential pair, which is an example illustrating a part of the signal connection structure, and the signal connection structure can include a plurality of differential pairs to have the similar effects.

The embodiments of the present disclosure illustrate an example of the structure, dimension, material, or the like of each component in the configuration, manufacturing method, and the like of the trace structure, but without limitation, any structure, dimension, material, or the like is applicable as long as the functions of the trace structure are exhibited, and the effects are provided.

### INDUSTRIAL APPLICABILITY

Embodiments of the present disclosure can be applied to a trace substrate, a mounting substrate, or the like in a high-frequency electronic device, or a semiconductor apparatus.

1-8. (canceled)

9. A trace structure comprising:
a first signal line comprising a first outer layer conductor disposed on a top surface of a dielectric substrate, a first via, a first inner layer conductor disposed inside the dielectric substrate, a second via, and a second outer layer conductor disposed on a bottom surface of the dielectric substrate, wherein the first outer layer conductor, the first via, the first inner layer conductor, the second via, and the second outer layer conductor are electrically connected to each other; and
a second signal line comprising a third outer layer conductor disposed on the top surface of the dielectric substrate, a third via, a second inner layer conductor disposed inside the dielectric substrate, a fourth via, and a fourth outer layer conductor disposed on the bottom surface of the dielectric substrate, wherein the third outer layer conductor, the third via, the second inner layer conductor, the fourth via, and the fourth outer layer conductor are electrically connected to each other;
wherein the first inner layer conductor and the second inner layer conductor have substantially equivalent lengths and are arranged on different planes each parallel to the bottom surface to overlap each other in a vertical direction; and
a sum of a length of the first via and a length of the second via is substantially equivalent to a sum of a length of the third via and a length of the fourth via.

10. The trace structure according to claim 9, wherein the first inner layer conductor and the second inner layer conductor are arranged to be symmetric with respect to a substrate center plane parallel to the bottom surface.

11. The trace structure according to claim 9, wherein the dielectric substrate comprises a multilayer structure, and wherein a dielectric constant of a layer including the first inner layer conductor and the second inner layer conductor is lower than a dielectric constant of a layer not including the first inner layer conductor and the second inner layer conductor.

12. The trace structure according to claim 11, wherein layer thicknesses of layers in the multilayer structure are substantially equivalent.

13. The trace structure according to claim 9, further comprising conductors connected to a ground and disposed to sandwich the first inner layer conductor and the second inner layer conductor in a top-to-bottom direction.

14. The trace structure according to claim 9, wherein:
an end portion of the first via proximate to the top surface and an end portion of the second via proximate to the bottom surface are arranged to be point-symmetric with respect to a center point of the first inner layer conductor; and
an end portion of the third via proximate to the top surface and an end portion of the fourth via proximate to the bottom surface are arranged to be point-symmetric with respect to a center point of the second inner layer conductor.

15. The trace structure according to claim 9, wherein:
the first via and the second via are arranged to be line-symmetric with respect to a line that passes through a center point of the first inner layer conductor and is perpendicular to a signal transmission direction when viewed from the top surface; and
the third via and the fourth via are arranged to be line-symmetric with respect to a line that passes through a center point of the second inner layer conductor and is perpendicular to the signal transmission direction when viewed from the top surface.

16. The trace structure according to claim 9, wherein:
a positive phase signal is transmitted through the first signal line and a negative phase signal is transmitted through the second signal line; and
the first inner layer conductor and the second inner layer conductor constitute a broad side differential trace.

17. The trace structure according to claim 9, wherein:
a positive phase signal is transmitted through the second signal line and a negative phase signal is transmitted through the first signal line; and
the first inner layer conductor and the second inner layer conductor constitute a broad side differential trace.

18. A wiring structure comprising:
a multi-layer dielectric substrate;
first and second outer layer conductors on a top surface of the substrate;
third and fourth outer layer conductors on a bottom surface of the substrate;
first, second, third, and fourth inner layer conductors in an inner layer of the substrate;
first, second, third, and fourth vias in the inner layer of the substrate; and
first, second, third, and fourth expansion parts in the inner layer of the substrate;
wherein the first outer layer conductor, the first via, the first inner layer conductor, the third via, and the third outer layer conductor are electrically connected to each other;
wherein the second outer layer conductor, the second via, the second inner layer conductor, the fourth via, and the fourth outer layer conductor are electrically connected to each other;
wherein the first inner layer conductor and the second inner layer conductor are wired on different planes parallel to the bottom surface of the substrate to overlap each other in a vertical direction; and
wherein a sum of a length of the first via and the third via is substantially equivalent to a sum of a length of the second via and the fourth via.

19. The wiring structure according to claim 18, wherein the multi-layer dielectric substrate comprises an upper layer, an intermediate layer, and a lower layer, and wherein a material of each of the upper layer, the intermediate layer, and the lower layer is ceramic.

20. The wiring structure according to claim 18, wherein the multi-layer dielectric substrate comprises an upper layer, an intermediate layer, and a lower layer, and wherein a material of the upper layer and the lower layer is different from a material of the intermediate layer.

21. The wiring structure according to claim 18, wherein the third inner layer conductor and the fourth inner layer conductor are wired as ground conductors symmetrically with respect to a substrate center plane, in which the third inner layer conductor is wired over the first inner layer conductor and the fourth inner layer conductor is wired under the second inner layer conductor.

22. The wiring structure according to claim 18, wherein the first inner layer conductor and the second inner layer conductor are arranged to be symmetric with respect to a substrate center plane parallel to the bottom surface.

23. The wiring structure according to claim 18, wherein a dielectric constant of a layer of the multi-layer dielectric substrate that includes the first inner layer conductor and the second inner layer conductor is lower than a dielectric constant of a layer of the multi-layer dielectric substrate that does not include the first inner layer conductor and the second inner layer conductor.

24. The wiring structure according to claim 18, wherein layer thicknesses of layers in the multi-layer dielectric substrate are substantially equivalent.

25. The wiring structure according to claim 18, wherein:
an end portion of the first via proximate to the top surface and an end portion of the second via proximate to the bottom surface are arranged to be point-symmetric with respect to a center point of the first inner layer conductor; and
an end portion of the third via proximate to the top surface and an end portion of the fourth via proximate to the bottom surface are arranged to be point-symmetric with respect to a center point of the second inner layer conductor.

26. The wiring structure according to claim 18, wherein:
the first via and the second via are arranged to be line-symmetric with respect to a line that passes through a center point of the first inner layer conductor and is perpendicular to a signal transmission direction when viewed from the top surface; and
the third via and the fourth via are arranged to be line-symmetric with respect to a line that passes through a center point of the second inner layer conductor and is perpendicular to the signal transmission direction when viewed from the top surface.
